(19) United States
(12) Patent Application Publication
(10) Pub. No.: US 2007/0215284 A1
(43) Pub. Date: Sep. 20, 2007

(54) PLASMA PROCESSING APPARATUS AND ELECTRODE ASSEMBLY FOR PLASMA PROCESSING APPARATUS

(75) Inventor: Jun OYABU, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/685,991

(22) Filed: Mar. 14, 2007

Related U.S. Application Data
(60) Provisional application No. 60/786,028, filed on Mar. 27, 2006.

(30) Foreign Application Priority Data
Mar. 16, 2006 (JP) 2006-072682

(51) Int. Cl. C23F 1/00; H01L 21/306; C23C 16/00

(52) U.S. Cl. 156/345.47; 156/345.51; 118/723 E; 118/728

(57) ABSTRACT

An electrode assembly, for use in a plasma processing apparatus which generates a plasma by forming a high frequency electric field in a processing chamber accommodating a substrate to be processed, includes a plate shaped member formed of a metal matrix composite material. The plate shaped member has an electric resistance distribution such that an electric resistance in a central portion of the plate shaped member is greater than that in a peripheral portion thereof.

### FIELD OF THE INVENTION

The present invention relates to a plasma processing apparatus for performing plasma processing such as plasma etching, and an electrode assembly for the plasma processing apparatus.

### BACKGROUND OF THE INVENTION

In a manufacturing process of a semiconductor device or a liquid crystal display device, plasma processing is mostly adopted which performs various processes using plasma. A typical example of such a plasma processing apparatus is a so-called parallel plate type plasma processing apparatus, which has a pair of electrodes facing each other in order to form a high frequency electric field therebetween, thereby generating a plasma.

Recently, in order to improve the productivity of a process for manufacturing semiconductor devices, the diameter of a semiconductor wafer, which is a substrate to be processed, has been gradually increased. Hence, there arises a need to improve an in-surface uniformity of plasma processing for such a parallel plate type plasma processing apparatus. The in-surface uniformity is improved by generating a plasma of uniform density in a large area.

The above-mentioned plasma density is usually higher in a central portion and lower in a peripheral portion of the electrode. Therefore, there has been proposed an electrode assembly for a plasma processing apparatus having an electrode surface member (formed of, e.g., silicon) which forms an exposed surface in a processing chamber, a member positioned at a backside of the electrode surface member, such as a spacer, and a gap formed therebetween only in a central portion, for providing uniform plasma density. There has been proposed another configuration where the central portion and the peripheral portion of, e.g., the electrode surface member are separately formed of materials having different electric resistance, to achieve uniform plasma density. (see, e.g., Japanese Patent Laid-open Application No. 2000-323456)

The above-described configuration having a gap formed between the electrode surface member and the member positioned in back thereof, such as the spacer, has a problem that there may occur an abnormal electric discharge in the gap. Further, in the configuration where the central portion and the peripheral portion of, e.g., the electrode surface member are separately formed of materials having different electric resistance, the number of constituent parts is increased, and therefore assembling, maintenance or repairing of the electrode assembly is made troublesome.

### SUMMARY OF THE INVENTION

The present invention is to solve the aforementioned problems; and it is, therefore, an object of the present invention to provide a plasma processing apparatus and an electrode assembly for the plasma processing apparatus capable of performing plasma processing at a high level of in-surface uniformity, by achieving uniform plasma density without causing abnormal electric discharge or troublesomeness in assembling, maintenance and repairing.

In accordance with a first aspect of the invention, there is provided an electrode assembly, for use in a plasma processing apparatus which generates a plasma by forming a high frequency electric field in a processing chamber accommodating a substrate to be processed. The electrode assembly includes a plate shaped member formed of a metal matrix composite material and having an electric resistance distribution such that an electric resistance in a central portion of the plate shaped member is greater than that in a peripheral portion thereof.

In the present invention, it is preferable that the plate shaped member is an electrode surface member that forms an exposed surface in the processing chamber.

Further, it is also preferable that the plate shaped member is a member positioned at a backside of an electrode surface member that forms an exposed surface in the processing chamber.

Further, it is also preferable that the plate shaped member has a middle portion, the middle portion being positioned between the central portion and the peripheral portion, and having an electric resistance smaller than that of the central portion but greater than that of the peripheral portion.

In accordance with a second aspect of the invention, there is provided a plasma processing apparatus, having the electrode assembly of the first aspect of the invention, wherein the plasma processing apparatus is constructed to supply a high frequency power to the electrode assembly.

In accordance with a second aspect of the invention, there is provided a plasma processing apparatus, having the electrode assembly of the first aspect of the invention, wherein the plasma processing apparatus is constructed such that the electrode assembly has a ground potential.

In accordance with aspects of the present invention, there is provided a plasma processing apparatus and an electrode assembly of the plasma processing apparatus capable of performing plasma processing at a high level of in-surface uniformity, by achieving uniform plasma density without causing abnormal electric discharge or troublesomeness in assembling, maintenance and repairing.

### BRIEF DESCRIPTION OF THE DRAWINGS

The above and other objects and features of the present invention will become apparent from the following description of preferred embodiments given in conjunction with the accompanying drawings, in which:

FIG. 1 is a schematic view showing an overall configuration of a plasma etching apparatus in accordance with an embodiment of the present invention;

FIG. 2 presents a schematic view of a main part of the plasma etching apparatus shown in FIG. 1;

FIG. 3 illustrates a distributional state of electric resistance;

FIG. 4 illustrates another distributional state of electric resistance; and

FIG. 5 offers a schematic view showing an overall configuration of a plasma etching apparatus in accordance with another embodiment of the present invention.

### DETAILED DESCRIPTION OF EMBODIMENTS

Hereinafter, preferred embodiments of the present invention will be described with reference to the accompanying drawings. Here, it is to be noted that the present invention is not limited thereto.

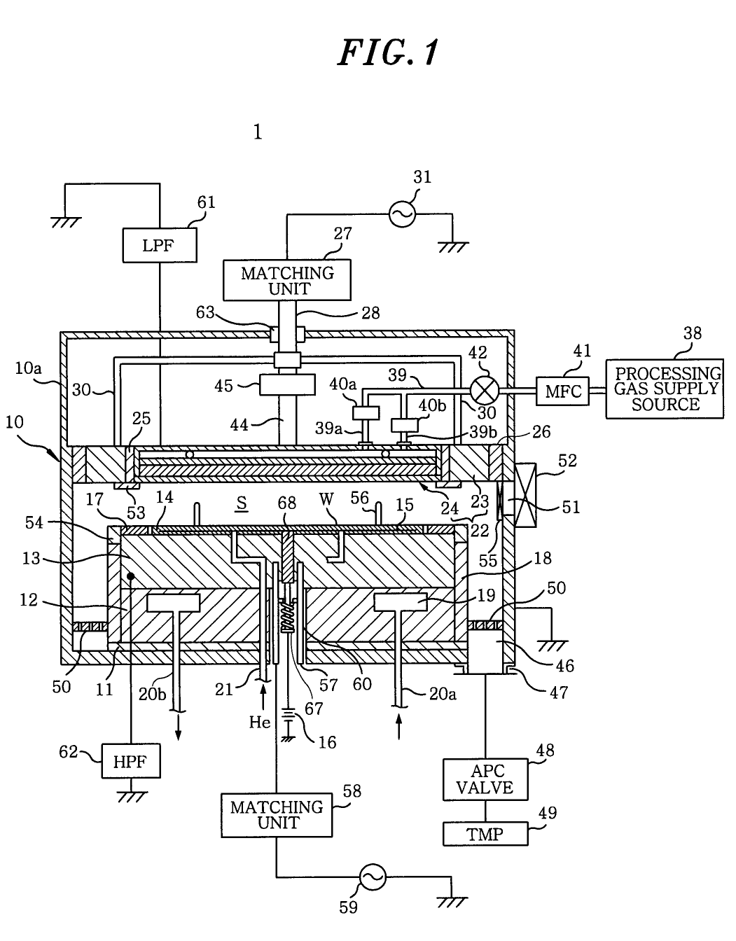

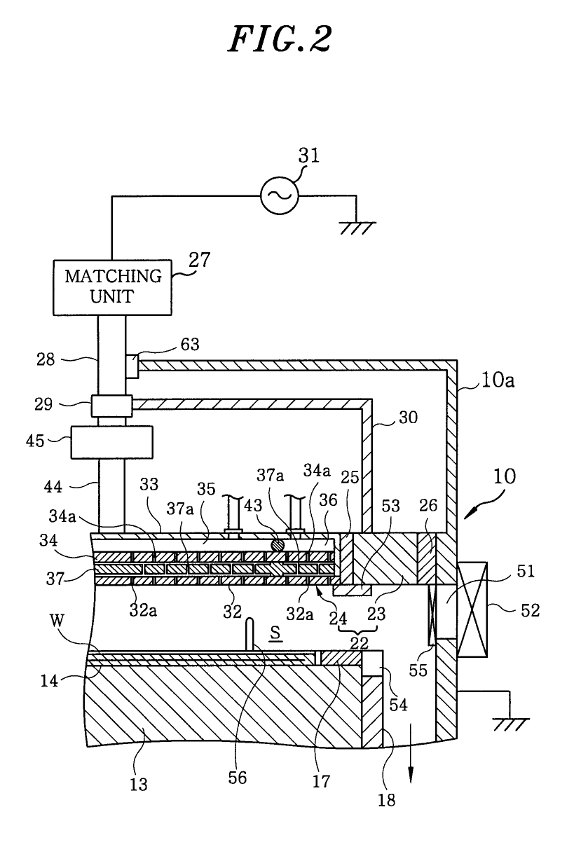

FIG. 1 is a schematic view showing an overall cross-sectional configuration of a plasma etching apparatus as a plasma processing apparatus in accordance with an embodiment of the present invention, while FIG. 2 shows a cross sectional configuration of a main part of the plasma etching apparatus shown in FIG. 1.

A plasma etching apparatus 1 is a capacitively coupled parallel plate type etching apparatus. The plasma etching apparatus 1 is provided with electrode plates positioned in parallel facing each other horizontally, and a power supply for generating a plasma connected thereto.

The plasma etching apparatus 1 is formed of, e.g., aluminum having an anodized surface, and is provided with a cylindrically shaped processing chamber (processing vessel) 10, wherein the processing chamber 10 is grounded. On a base portion of the processing chamber 10, there is provided a susceptor supporting table 12 of an almost cylindrical shape. The susceptor supporting table 12 is for mounting an object to be processed which is, e.g., a semiconductor wafer W, through an insulating plate 11 formed of ceramic or such. On the susceptor supporting table 12 is provided a susceptor 13 which forms a lower electrode. To the susceptor 13, a high pass filter (HPF) 62 is connected.

A coolant chamber 19 is provided in the susceptor supporting table 12, so that a coolant is introduced and circulated through coolant lines 20a and 20b. Hence, the cold heat from the circulation of the coolant is thermally conducted to the semiconductor wafer W through the susceptor 13, to thereby control the temperature of the semiconductor wafer W maintained at a desired level.

On the susceptor 13, there is provided an electrostatic chuck 14 having an almost identical form of the semiconductor wafer W. The electrostatic chuck 14 includes an electrode plate 15 formed of a conductive film, and a pair of insulating layers or insulating sheets between which the electrode plate 15 is inserted. A DC power source 16 is electrically connected to the electrode plate 15 through a connecting terminal 68 and a movable power feed rod 67, which will be described later. The electrostatic chuck 14 adsorptively supports the semiconductor wafer W through a Coulomb force or a Johnsen-Rahbek force generated from a DC voltage applied by the DC power source 16.

In the susceptor 13, a plurality of pusher pins 56 are provided such that the pusher pins 56 can be protruded from the top surface of the electrostatic chuck 14. The pusher pins 56 are driven by a driving mechanism including, e.g., a motor and a ball screw to support the semiconductor wafer W above the electrostatic chuck 14 when transferring the semiconductor wafer W to and from a transfer robot.

There is arranged a focus ring 17 on the susceptor 13, such that an outer periphery of the electrostatic chuck 14 is surrounded by the focus ring 17. The focus ring 17, which is formed of silicon or such, operates to improve etching uniformity. Around the focus ring 17 is situated a cover ring 54 for protecting a side portion of the focus ring 17. Likewise, around the side surface of the susceptor 13 and the susceptor supporting table 12, there is provided a cylindrically shaped inner wall member 18 formed of, e.g., quartz.

In the insulating plate 11, the susceptor supporting table 12, the susceptor 13 and the electrostatic chuck 14, a gas channel 21 is formed to supply thermal conduction medium (e.g., He gas) to a backside of the semiconductor wafer W. The cold heat of the susceptor 13 is transferred to the semiconductor wafer W through the thermal conduction medium, so that the temperature of the semiconductor wafer W is maintained to a certain level.

There is also provided an upper electrode 22 above the susceptor 13, parallelly facing the susceptor. A space between the susceptor 13 and the upper electrode 22 functions as a plasma generation space S. The upper electrode 22 is formed of an outer upper electrode 23 having an annular shape, and an inner upper electrode 24 having a disc shape. The inner upper electrode 24 is arranged inside of the outer upper electrode 23.

A dielectric material 25 formed of, e.g., quartz is situated in between the inner upper electrode 24 and the outer upper electrode 23, as an insulator. By interposing the dielectric material 25 between the inner upper electrode 24 and the outer upper electrode 23, a condenser is formed therebetween. The capacitance of the condenser is set to have a desired value by setting a size of a gap between the inner upper electrode 24 and the outer upper electrode 23 and a dielectric constant of the dielectric material 25. Further, an annularly shaped insulating shield member 26 formed of, e.g., alumina or yttrium oxide, is airtightly arranged between the outer upper electrode 23 and a side wall of the processing chamber 10.

The outer upper electrode 23 is formed of, e.g., silicon. The outer upper electrode 23 is electrically connected to a first high frequency power source 31 through a power feed barrel 30, a connector 29, a power feed rod 28 and a matching unit 27, as shown in FIG. 2. The first high frequency power source 31 outputs a high frequency voltage of which the frequency is higher than 13.5 MHz, e.g., the frequency is 60 MHz.

The power feed barrel 30 is formed of a substantially cylindrically or conically shaped conductive plate such as an aluminum plate or a copper plate. A lower end of the power feed barrel 30 is continuously in contact with the outer upper electrode 23 along the circumferential direction, and an upper end of the power feed barrel 30 is electrically connected to the power feed rod 28 through the connector 29. At an outside of the power feed barrel 30, the side wall of the processing chamber 10 is extended over the height of the upper electrode 22, to form a cylindrically shaped grounding conductor 10a. The upper part of the cylindrically shaped grounding conductor 10a is electrically insulated from the power feed rod 28 by means of a barrel shaped insulating member 63.

In a load circuit seen from the connector 29 in this configuration, a coaxial line having the power feed barrel 30 and the outer upper electrode 23 as its waveguide is formed by the power feed barrel 30, the outer upper electrode 23 and the cylindrically shaped grounding conductor 10a.

The inner upper electrode 24 is provided with a number of gas holes 32a and an electrode surface member 32 which forms an exposed surface in the processing chamber 10. A cooling plate 34 provided at a backside of the electrode surface member 32, likewise, has a number of gas holes 34a. And a spacer 37 that is provided between the cooling plate 34 and the electrode surface member 32, likewise again, has a number of gas holes 37a. Inside the cooling plate 34, a coolant circulating mechanism which is not shown is provided to set to a desired temperature.

The electrode surface member 32, the spacer 37 and the cooling plate 34 are supported as a unit by an electrode supporting member 33. The electrode surface member 32 is clamped to the electrode supporting member 33 by bolts which are not shown. The head portions of the bolts are protected by an annularly shaped shield ring 53 arranged below the electrode surface member 32.

Inside the electrode supporting member 33, a buffer chamber is formed to which a processing gas is introduced, which will be described later. The buffer chamber is formed of a central buffer chamber 35 and a peripheral buffer chamber 36 separated from each other by an annularly shaped partition wall member 43 including, e.g., an O-ring.

In the present embodiment, the electrode assembly for the plasma processing apparatus is formed of the electrode surface member 32, the spacer 37, the cooling plate 34 and the electrode supporting member 33, which are replaced as a unit in the course of maintenance and repairing of the plasma etching apparatus 1. At least one of the electrode surface member 32, the spacer 37 and the cooling plate 34 are formed of a plate shaped member being formed of a metal matrix composite material and having an electric resistance distribution such that a central portion has a greater electric resistance than that in a peripheral portion thereof. Metal matrix composite materials, e.g., produced by Nihon Ceratec Co., Ltd. may be used as the metal matrix composite material mentioned above.

In such a metal matrix composite material, a content ratio of a metal to a ceramic may be adjusted to form a singular member having regions of which electric resistance is different from each other. Therefore, the electrode surface member 32, the spacer 37 and the cooling plate 34 can be produced to have a greater electric resistance in the central portion than in the peripheral portion. Furthermore, in case of forming the electrode surface member 32 with a metal matrix composite material, it is preferable to use silicon as a base material. However, in case of forming the spacer 37 or the cooling plate 37 with a metal matrix composite material, it is preferable to use aluminum alloy or such as a base material.

As described above, by forming at least one of the electrode surface member 32, the spacer 37 and the cooling plate 34 with a plate shaped member being formed of a metal matrix composite material and having an electric resistance distribution such that the central portion has a greater electric resistance than that in the peripheral portion, an effect of suppressing a rise of a plasma density in the central region is made achievable, thereby realizing high level of in-surface uniformity in plasma processing. Such an effect is equivalent to that obtained by providing a gap only in the central portion between, e.g., the electrode surface member 32 and the spacer 37. In addition, an abnormal electric discharge is prevented from being generated in the gap, for the gap is not formed in this configuration. Further, by providing the plate shaped member formed as a unit, sophistication of the structure or troublesomeness to assembling, maintenance or repairing is prevented which would otherwise be caused when formed with a plurality of separate members.

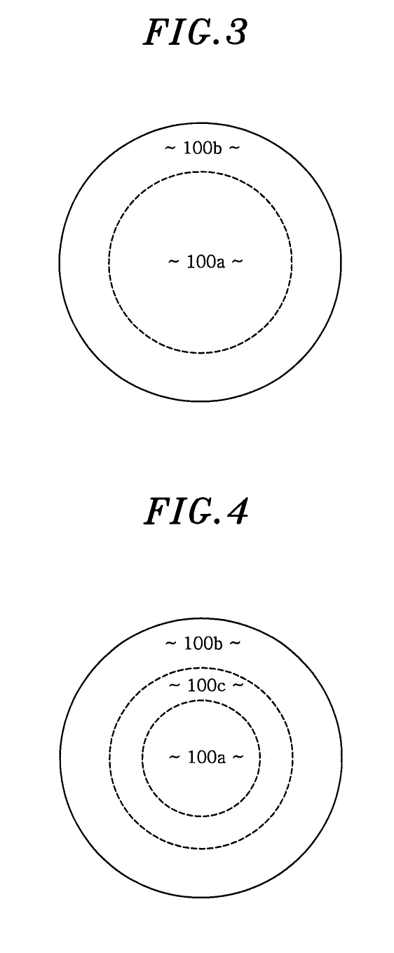

The distribution of the electric resistance may be constituted with two different regions of a central portion 100a and a peripheral portion 100b, as illustrated in FIG. 3. However, as schematically illustrated in FIG. 4, the distribution of the electric resistance may be constituted with three different regions by providing an middle portion 100c in between the central portion 100a and the peripheral portion 100b. The electric resistance of the intermediate region 100c is set to be smaller than that of the central portion 100a but greater than that of the peripheral portion 100b. Or otherwise, the distribution of the electric resistance may be constituted with more number of different regions.

The metal matrix composite material described above may be used for other constituent parts of the plasma etching apparatus 1. As an example, the processing chamber 10 may be formed of a metal matrix composite material and provided therein a heating layer and an insulating layer enclosing the heating layer, while the surface layer is formed of a conductive layer, thereby forming an integrated chamber with a built-in heater. Such a configuration enables the temperature of a wall surface of the processing chamber 10 to be controlled, and facilitates handling in case of, e.g., cleaning, compared with when a separate heater or a peltier element is attached.

The electrode supporting member 33 of the inner upper electrode 24 is electrically connected to the first high frequency power source 31 through the matching unit 27, the power feed rod 28, the connector and an upper power feed barrel 44. There is arranged a variable condenser 45 having a capacitance capable of being variably adjusted, in the middle of the upper power feed barrel 44.

As illustrated in FIG. 1, a processing gas supply source 38 is provided outside of the processing chamber 10. A processing gas is supplied to the central buffer chamber 35 and the peripheral buffer chamber 36 at a desired flow rate ratio from the processing gas supply source 38. For such a configuration, the gas supply line 39 from the processing gas supply source 38 is ramified into branch lines 39a and 39b on the way, and connected to the central buffer chamber 35 and the peripheral buffer chamber 36 through flow rate control valves 40a and 40b. Usually, a mass flow controller (MFC) 41 and a switching valve 42 are interposed in the middle of the gas supply line 39.

On the base portion of the processing chamber 10 is provided an exhaust port 46, which is connected to an automatic pressure control (APC) valve 48 and a turbo molecular pump (TMP) 49 through an exhaust manifold 47. The automatic pressure control valve 48 and the turbo molecular pump 49 cooperate to form a reduced pressure atmosphere in the processing chamber 10, by vacuum exhausting down to a predetermined pressure level, e.g., below 1 Pa. Further, an annularly shaped baffle plate 50 having a plurality of vent holes is arranged between the exhaust port 46 and the plasma generation space S, in a manner that surrounds the susceptor supporting table 12. The baffle plate 50 prevents plasma leakage from the plasma generation space S to the exhaust port 46.

On the side wall of the processing chamber 10, a loading/unloading gate 51 for the semiconductor wafer W is provided and a gate valve 52 is provided therewith. When the gate valve 52 is open, the semiconductor wafer W is transferred to or from the load-lock chamber (not shown) through the loading/unloading gate 51. There is also provided a shutter 55 between the loading/unloading gate 51 and the plasma generation space S. The shutter 55 functions as a slide valve which is driven by air pressure to move up/down. When the gate valve 52 is opened to perform transfer of the semiconductor wafer W into or out of the plasma generation space S, the shutter 55 isolates the loading/unloading gate 51 from the plasma generation space S, for preventing plasma leakage through the loading/unloading gate 51.

The susceptor 13, which is a lower electrode, is connected to a second high frequency power source 59 through a lower power feed barrel 57 and a matching unit 58. The frequency of the second high frequency power source 59 is preferably set to range from 2 to 27 MHz. In an inner space of the lower power feed barrel 57, there is exposed an end portion of a connecting terminal 68 which is connected to the electrode plate 15 of the electrostatic chuck 14 while penetrating the susceptor 13. There is also provided a movable power feed rod 67 which is moved up/down in the inner space. The power feed rod 67 is moved upward to make a contact with the connecting terminal 68 in case a DC voltage is applied to the electrode plate 15 from the DC power source 16. In a like manner, the power feed rod is moved downward to release the contact with the connecting terminal 68 in case a DC voltage is not applied to the electrode plate 15 from the DC power source 16.

The movable power feed rod 67 has a flange formed on its base portion, and the lower power feed barrel 57 also has a flange protruding toward the inner space. There is arranged a spring 60 formed of silicon nitride (SiN) which is an insulating material, between the flange of the movable power feed rod 67 and the flange of the lower power feed barrel 57, thereby to restrict up/down movement of the power feed rod 67. By forming the spring with an insulating material, an electromagnetic induction caused by a high frequency power is prevented from being generated, and the spring 60 is prevented from having a high temperature, which, in turn, prevents deterioration thereof.

The inner upper electrode 24 is connected to a low pass filter (LPF) 61, which blocks a high frequency power from the first high frequency power source 31 to a ground and passes a high frequency power from the second high frequency power source 59 to a ground. On a susceptor's side, there is provided a high pass filter (HPF) 62 connected thereto for passing a high frequency power from the first high frequency power source 31 to a ground.

The procedure of performing plasma etching of the semiconductor wafer W using the plasma etching apparatus 1 of an above-described configuration is as follows. Once the gate valve 52 is opened, the semiconductor wafer W is loaded into the processing chamber 10 from the load-lock chamber which is not shown, and mounted on the electrostatic chuck 14. Then, the semiconductor wafer W is electrostatically adsorbed on the electrostatic chuck 14, as a DC voltage is applied from the DC power source 16 to the electrode plate 15 of the electrostatic chuck 14. After that, the gate valve 52 is closed and the processing chamber 10 is vacuum exhausted to a predetermined vacuum level by means of the automatic pressure control valve 48 and the turbo molecular pump 49.

A switching valve 42 is opened thereafter, a predetermined processing gas (etching gas) is introduced from the processing gas supply source 38 to the plasma generation space S of the processing chamber 10 through the central buffer chamber 35 and the peripheral buffer chamber 36. A flow rate of the processing gas is controlled by the mass flow controller 41.

Then a pressure in the processing chamber 10 is maintained to a predetermined pressure level, after which a high frequency power of a predetermined frequency is applied from the first high frequency power source 31 to the upper electrode 22. By doing so, a high frequency electric field is generated between the upper electrode 22 and the susceptor 13 which is a lower electrode, thereby the processing gas being dissociated to be converted into plasma.

From the second high frequency power source 59, a high frequency power of a frequency lower than that from the first high frequency power source 31 is applied to the susceptor 13, a lower electrode. Therefore, ions in the plasma are attracted to the susceptor 13, and an etching anisotropy is increased by ion-assist.

Further, in the inner upper electrode 24, a ratio of flow rates of the processing gas injected at a central shower head and a peripheral shower head, each of which is facing the semiconductor wafer W, is arbitrarily controllable. From this, a spatial distribution of gas molecules or a radical density is controlled in a diametrical direction of the semiconductor wafer W, thereby arbitrarily controlling a spatial distribution of etching properties due to a radical base.

Further, in the upper electrode 22, adopting the outer upper electrode 23 as a main high frequency electrode and the inner upper electrode 24 as a subsidiary high frequency electrode for generating a plasma, a ratio of electric field intensities given to the electrons right beneath the upper electrode 22 is adjusted by using the first high frequency power source 31 and the second high frequency power source 59. As a consequence, spatial distribution of an ion density is controlled in a diametrical direction, thereby enabling an arbitrary and fine control of spatial properties of reactive ion etching.

Further, in the inner upper electrode 24, at least one of the electrode surface member 32, the spacer 37 and the cooling plate 34 are formed of a metal matrix composite material having an electric resistance distribution such that a central portion has a higher electric resistance than that in a peripheral portion. Due to such a configuration, the high frequency electric field intensity at the central region is reinforced, and a plasma density therein is prevented from rising, by which a high level of in-surface uniformity is achieved in plasma processing.

When the plasma etching is completed, supply of the high frequency powers and the processing gas stops, and the semiconductor wafer W is unloaded from the processing chamber 10, in reverse order of the steps mentioned above.

As described above, in accordance with this embodiment, uniform plasma density and, in turn, high level of in-surface uniformity in plasma processing are achieved without generating an abnormal electric discharge or introducing troublesomeness in assembling, maintenance and repairing.

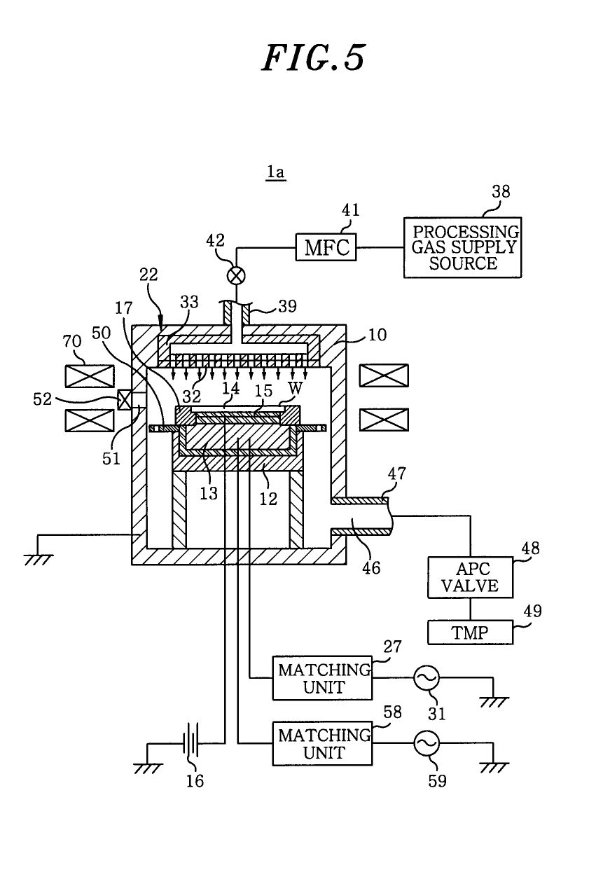

The present invention is not limited to the above-mentioned embodiment, but is allowed to be modified in many different ways. As an example, the plasma etching apparatus of the present invention is not limited to the parallel plate type where each of the high frequency powers are applied from the upper and the lower electrode, respectively, as shown in FIGS. 1 and 2. The present invention may be likewise applied to a lower-side dual frequency application type plasma etching apparatus la shown in FIG. 5, where the first high frequency power source 31 and the second high frequency power source 59 are connected to the lower electrode (susceptor 13).

In the plasma etching apparatus 1a of FIG. 5, like parts are given like reference characters, to avoid repeated description. However, in this case, the upper electrode 22 is electrically connected to a ground to have a ground potential. The same effect as that of the previously said embodiment can be obtained by forming the electrode surface member 32 included in the upper electrode 22 with a metal matrix composite material having an electric resistance distribution such that a central portion has a higher electric resistance than that in a peripheral portion. Further, in the plasma etching apparatus 1a of FIG. 5, there is provided a rotatable magnet 70 outside of the processing chamber 10, thereby forming a magnetic field in the processing chamber 10 to control plasma.

While the invention has been shown and described with respect to the preferred embodiments, it will be understood by those skilled in the art that various changes and modifications may be made without departing from the scope of the invention as defined in the following claims.

What is claimed is:

1. An electrode assembly, for use in a plasma processing apparatus which generates a plasma by forming a high frequency electric field in a processing chamber accommodating a substrate to be processed, the electrode assembly comprising:
a plate shaped member being formed of a metal matrix composite material and having an electric resistance distribution such that an electric resistance in a central portion of the plate shaped member is greater than that in a peripheral portion thereof.

2. The electrode assembly of claim 1, wherein the plate shaped member is an electrode surface member that forms an exposed surface in the processing chamber.

3. The electrode assembly of claim 1, wherein the plate shaped member is a member positioned at a backside of an electrode surface member that forms an exposed surface in the processing chamber.

4. The electrode assembly of claim 1, wherein the plate shaped member has a middle portion, the middle portion being positioned between the central portion and the peripheral portion, and having an electric resistance smaller than that of the central portion but greater than that of the peripheral portion.

5. The electrode assembly of claim 2, wherein the plate shaped member has a middle portion, the middle portion being positioned between the central portion and the peripheral portion, and having an electric resistance smaller than that of the central portion but greater than that of the peripheral portion.

6. The electrode assembly of claim 3, wherein the plate shaped member has a middle portion, the middle portion being positioned between the central portion and the peripheral portion, and having an electric resistance smaller than that of the central portion but greater than that of the peripheral portion.

7. A plasma processing apparatus having the electrode assembly disclosed in claim 1, wherein the plasma processing apparatus is constructed to supply a high frequency power to the electrode assembly.

8. A plasma processing apparatus having the electrode assembly disclosed in claim 2, wherein the plasma processing apparatus is constructed to supply a high frequency power to the electrode assembly.

9. A plasma processing apparatus having the electrode assembly disclosed in claim 3, wherein the plasma processing apparatus is constructed to supply a high frequency power to the electrode assembly.

10. A plasma processing apparatus having the electrode assembly disclosed in claim 4, wherein the plasma processing apparatus is constructed to supply a high frequency power to the electrode assembly.

11. A plasma processing apparatus having the electrode assembly disclosed in claim 5, wherein the plasma processing apparatus is constructed to supply a high frequency power to the electrode assembly.

12. A plasma processing apparatus having the electrode assembly disclosed in claim 6, wherein the plasma processing apparatus is constructed to supply a high frequency power to the electrode assembly.

13. A plasma processing apparatus having the electrode assembly disclosed in claim 1, wherein the plasma processing apparatus is constructed such that the electrode assembly has a ground potential.

14. A plasma processing apparatus having the electrode assembly disclosed in claim 2, wherein the plasma processing apparatus is constructed such that the electrode assembly has a ground potential.

15. A plasma processing apparatus having the electrode assembly disclosed in claim 3, wherein the plasma processing apparatus is constructed such that the electrode assembly has a ground potential.

16. A plasma processing apparatus having the electrode assembly disclosed in claim 4, wherein the plasma processing apparatus is constructed such that the electrode assembly has a ground potential.

17. A plasma processing apparatus having the electrode assembly disclosed in claim 5, wherein the plasma processing apparatus is constructed such that the electrode assembly has a ground potential.

18. A plasma processing apparatus having the electrode assembly disclosed in claim 6, wherein the plasma processing apparatus is constructed such that the electrode assembly has a ground potential.
